(19) United States
(12) Patent Application Publication
(10) Pub. No.: US 2026/0230076 A1
(43) Pub. Date: Aug. 6, 2026

(54) Input Logic Level Voltage Selection Based on a Communication Voltage

(71) Applicant: TEXAS INSTRUMENTS INCORPORATED, DALLAS, TX (US)

(72) Inventors: Vishal SHAW, HOWRAH (IN); Matthew SCHURMANN, WYLIE, TX (US); Mayank JAIN, BANGALORE (IN); Kevin LA ROSA, SACHSE, TX (US)

(21) Appl. No.: 19/042,555

(22) Filed: Jan. 31, 2025

(51) Int. Cl. H03K 19/0175

(52) U.S. Cl. CPC H03K 19/017509

(57) ABSTRACT

In a described example, a detector is configured to control a bus operating mode of a bus controller. The detector can be coupled to the bus controller. The detector includes a bus voltage detector that can be configured to provide a bus voltage detected signal indicative of a bus voltage level of a bus voltage on a communication bus. The bus controller can be configured to operate in a first bus mode. The detector can include logic that can be coupled to the bus voltage detector. The logic can be configured to determine whether the bus voltage is at a high bus voltage level or a low bus voltage level based on the bus voltage detected signal and instruct the bus controller to either continue operating in the first bus mode or to switch to operating in a second bus mode based on the determined bus voltage level.

### TECHNICAL FIELD

This description relates generally to power devices and more particularly to input logic voltage selection based on a communication voltage.

### BACKGROUND

Inter-integrated circuit (I2C) is a synchronous, multi-master, multi-slave, serial communication protocol for low-speed data exchange between components on the same circuit board. A system management bus (SMBus) is a subset of an I2C protocol that can be used for communicating with low-bandwidth devices (e.g., temperature sensors, power-related components, and battery controllers). A Power Management Bus (PMBus) is an open standard communication protocol (also a type of I2C protocol) that can be used to communicate with power conversion and other devices, such as voltage regulators (VRs) and other components. PMBus provides a flexible and reliable means for managing power conversion and regulation in various electronic systems.

### SUMMARY

One described example relates to a circuit. The circuit includes a detector that can be coupled to a bus controller. The detector includes a bus voltage detector and logic. The bus voltage detector is configured to provide a bus voltage detected signal indicative of a bus voltage level of a bus voltage on a communication bus. The bus controller can be configured to operate in a first bus mode. The logic can be coupled to the bus voltage detector. The logic is configured to determine whether the bus voltage is at a high bus voltage level or a low bus voltage level based on the bus voltage detected signal and instruct the bus controller to either continue operating in the first bus mode or to switch to operating in a second bus mode based on the determined bus voltage level.

In another described example, a circuit includes a detector having a first input and a second input, and an output. The first input of the detector can be coupled to a bus terminal and the second input of the detector can be coupled to a bus voltage threshold terminal. The circuit further includes a logic circuit having an input and first and second outputs. The input of the logic circuit can be coupled to the output of the detector. The circuit further includes a bus mode selector circuit having first, second and third inputs. The first input of the bus mode selector circuit can be coupled to the first output of the logic circuit, the second input of the bus mode selector circuit can be coupled to the second output of the logic circuit, and the third input of the bus mode selector circuit can be coupled to the bus terminal.

In yet another described example, a system can include a power device. The power device can include a bus controller and a detector. The bus controller can be coupled to a power management (PMBus) and configured to operate in a first bus mode. In the first bus mode, the bus controller can use a first input voltage threshold for interpreting bus signals transmitted on the PMBus. The detector is coupled to the PMBus. The detector can be configured to determine a bus voltage level on the PMBus based on a respective bus signal of the bus signals and instruct the bus controller to either continue operating in the first bus mode or switch to operating in a second bus mode based on the determined bus voltage level. In the second bus mode, the bus controller can use a second input voltage threshold for interpreting the bus signals.

### BRIEF DESCRIPTION OF THE DRAWINGS

FIG. 1 illustrates an example of a block diagram of a power management system.

FIG. 2 illustrates an example of a block diagram of a bus voltage detector.

FIG. 3 illustrates an example of a waveform diagram associated with a low voltage (LV) mode of operation of a bus voltage detector.

FIG. 4 illustrates an example of a waveform diagram associated with a high voltage (HV) mode of operation of a bus voltage detector.

FIG. 5 illustrates yet another example of a power management system.

FIG. 6 illustrates a further example of a power management system.

FIG. 7 illustrates an example of a flowchart of a method for controlling a bus operating mode of a bus controller.

### DETAILED DESCRIPTION

This description generally relates to power devices and more particularly to using a power management bus (PMBus) voltage for setting a bus operating mode of a bus controller.

A PMBus protocol (for simplicity referred herein as a protocol), as defined by IEC 62915-4 standard, is a communication protocol that is used to enable host devices (e.g., processors, controllers, etc.) to communicate with power devices (e.g., power conversion devices, such as voltages regulators (VRs)), and other devices. The protocol allows a host device to control the operating parameters of one or more power devices, such as a voltage being provided by these devices to a load. The protocol operates using a PMBus (referred to herein as a communication bus) so that information (e.g., commands) can be exchanged as bus signals between the host device and a power device. A supply voltage is used to establish a voltage on the communication bus, which can be referred to as a bus voltage, to allow the host device and the power devices to communicate information with each other.

The host device includes a host PMBus controller (referred to herein as a host bus controller) and the power device includes a secondary PMBus controller (referred to herein as a secondary bus controller). The host and the secondary bus controllers communicate to each other information by pulling down a bus voltage on the communication bus. To interpret each bus signal communicated by the host bus controller, so that the information therein can be extracted, the secondary bus controller compares each received (or incoming) bus signal on the communication bus to one or more input voltage thresholds (also known as input logic levels). The secondary bus controller uses the input voltage threshold to interpret a voltage level of the bus signal as a logic high (1) or a logic low (0) so that the information therein can be recovered. For the secondary bus controller to properly interpret the bus signals, the secondary bus controller needs to use proper input voltage thresholds (also referred to as input logic levels).

The PMBus protocol supports two operational modes: an HV bus mode and an LV bus mode. In the HV bus mode, the secondary bus controller interprets bus signals using a first set of input voltage thresholds. By contrast, in the LV bus mode, the secondary bus controller interprets bus signals using a second set of input voltage thresholds. Each set of input voltage thresholds can include an input voltage high threshold (VIH) and an input voltage low threshold (VIL). VIH is a minimum voltage at which a bus voltage level (e.g., a bus voltage amplitude) is interpreted as a logic high. VIL is a maximum voltage at which a bus voltage level is interpreted as a logic low. The VIH and VIL of the first set of input voltage thresholds can have a greater voltage level compared to the VIH and VIL of the second set of input voltage thresholds.

Power devices (e.g., power management devices, controllers, and/or control logic devices) are integrated circuit (IC) devices that are configured with bus controllers that operate either in the LV or HV bus mode. Bus controllers that operate in the HV bus mode can be referred to as HV bus mode controllers. HV bus mode controllers offer a greater noise margin between logic high and logic low states and are commonly used in environments (e.g., systems) with potentially high electronic noise. A larger noise margin makes HV bus mode controllers resilient to noise and signal degradation in noisy environments. By contrast, bus controllers that operate in the LV bus mode can be referred to as LV bus mode controllers. LV bus mode controllers are a low power option and have lower noise immunity as a noise margin between logic high and low states is smaller. System compatibility often determines whether HV or LV bus mode controllers are used, with HV-compatible input-output (I/O) options supporting higher voltages and offering greater robustness and availability. However, HV-compatible options may also involve higher costs or larger physical dimensions.

Each power device (e.g., power management device, as an example) is configured with a bus controller that operates either in the HV or LV bus mode. Thus, if a power device with an incorrect bus controller type is used this can lead to compatibility issues during system integration. For example, if a power device that is configured with a LV bus mode controller is used in a system that uses a supply voltage that is at a high supply voltage level (e.g., at about 1.8 Volts (V) or 3.3V) for the communication bus, the LV bus controller may not correctly interpret voltage levels of bus signals as logic high and lows due to the LV bus mode controller having a low noise margin (compared to an HV bus mode controller). Accordingly, the LV bus mode controller may not correctly interpret the voltage levels of the bus signals received from the host device when used in high supply voltage systems, which is known as a PMBus protocol failure. Such a failure results in the host device being unable to communicate with the voltage device properly. Thus, system designers need to ensure that a power device chosen for a system has a bus controller with proper input voltage threshold(s) for bus signal interpretation to avoid potential PMBus protocol failures during bus communication. This requires that system designers maintain separate bus mode configured power devices, one for HV bus mode scenarios, and another for LV bus mode scenarios.

According to the examples herein, a power device can be configured with a communication bus detector (for simplicity referred to herein as a detector). The detector can be configured to detect a bus voltage on a communication bus and use the detected bus voltage to set a bus operating mode of a bus controller of the power device, in some instances, referred to herein as a secondary bus controller. The bus voltage on the communication bus is established based on a supply voltage being provided by a voltage source of a system in which the power device is used. The bus voltage can be at a high bus voltage level and a low bus voltage level based on a voltage level of the supply voltage.

For example, the bus controller is configured to operate in an LV bus mode, which is a default bus operating mode of the bus controller. In the LV bus mode, the bus controller uses one or more LV input thresholds for bus signal interpretation. The detector is configured to instruct the bus controller to operate in an HV bus mode in response to determining that the bus voltage is at the high bus voltage level. In the HV bus mode, the bus controller uses one or more HV input thresholds for bus signal interpretation, which are at a greater voltage level when compared to the one or more LV input thresholds. In other examples, the detector is configured to allow the bus controller to continue operating in the LV bus mode when the bus voltage is at the low bus voltage level.

As a further example, the detector can detect the bus voltage and determine whether the bus voltage satisfies (e.g., is greater than or equal to) a bus voltage threshold signal. The detector can be configured to allow the bus controller to continue operating in the LV bus mode in response to determining that the bus voltage does not satisfy the bus voltage threshold signal (e.g., is less than the bus voltage threshold). In other examples, the detector can instruct the bus controller to operate in the HV bus mode in response to determining that the bus voltage satisfies the bus voltage threshold.

Configuring the power device with the detector, as described herein, eliminates a need to use separate power devices with bus controllers configured for specific voltage modes (e.g., LV and HV bus modes). This configuration simplifies system design and avoids potential compatibility issues during system integration. Additionally, because the power device itself cannot be configured for HV or LV mode without first establishing reliable communication, the detector is designed to automatically set the appropriate bus operating mode. This allows seamless switching between modes without disrupting an ongoing communication transaction (session) between the power device's bus controller and a host bus controller.

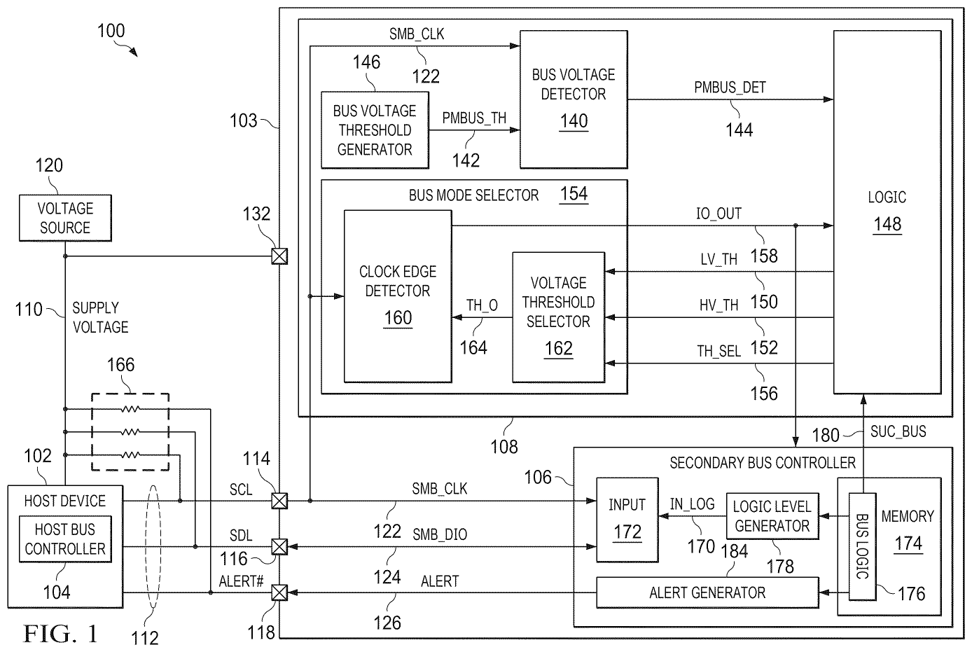

FIG. 1 illustrates an example of a block diagram of a system 100. The system 100 includes a host device 102 and a power device 103 (e.g., a power management device). The host device 102 includes a host bus controller 104. The power device 103 includes a secondary bus controller 106 and a detector 108. While the example of FIG. 1 illustrates the detector 108 as being implemented as a stand-alone circuit, in other examples, the secondary bus controller 106 includes the detector 108. The secondary bus controller 106 is configured to use one or more input voltage thresholds 170 (also known as input logic level voltages (or thresholds)) for bus signal interpretation. The detector 108 can set a bus mode of the secondary bus controller 106 based on a bus voltage.

For example, the secondary bus controller 106 can operate in an LV bus mode or an HV bus mode based on the bus voltage. The secondary bus controller 106 is configured to operate in the LV bus mode, for example, in response to being initialized (e.g., powered). The LV bus mode can be a default bus mode of the secondary bus controller 106 as the secondary bus controller 106 is automatically set to operate in this mode upon initialization. In the LV bus mode, the secondary bus controller 106 uses one or more LV input thresholds as the input voltage threshold 170 for bus signal interpretation. In the HV bus mode, the secondary bus controller 106 uses one or more HV input thresholds as the input voltage threshold 170 for bus signal interpretation. In some examples, the LV input thresholds include a first VIL and a first VIH (e.g., a VIL of about 0.4V and a VIH of about 0.75V, respectively). The HV input thresholds can include a second VIL and a second VIH (e.g., a VIL of about 0.8V and a VIH of about 1.35V, respectively).

In examples in which the system 100 provides a supply voltage 110 at a low supply voltage level (e.g., at about 1.2V), the detector 108 allows the secondary bus controller 106 to continue operating in the LV bus mode (e.g., the default bus mode). In examples in which the system 100 provides the supply voltage 110 at a high supply voltage level (e.g., at about 1.8V or 3.3V), the detector 108 instructs the secondary bus controller 106 to operate in the HV bus mode.

The host device 102 can receive the supply voltage 110, which in some instances, can be referred to as a VDD voltage. For example, in response to the system 100 being initialized (e.g., powered on), the voltage source 120 can provide the supply voltage 110 to the host device 102 to initiate (e.g., startup) the host bus controller 104, and thus initialize the host bus controller 104. The supply voltage 110 can be provided to an I/O pin 132 of the power device 103, which in some instances is known as a VDDIO pin. The supply voltage 110 received at the I/O pin 132 can be used to power the detector 108 and the secondary bus controller 106 of the power device 103.

The host bus controller 104 and the secondary bus controller 106 can be configured to communicate using a PMBus protocol over a PMBus 112 (for simplicity referred to herein as a communication bus 112). The communication bus 112 can include a serial data line (SDL) (also referred to as an SDA), a serial clock line (SCL), and in some instances, an alert line (ALERT #), as shown in FIG. 1. The communication bus 112 couples the power device 103 to the host device 102. The power device 103 includes a clock (CLK) terminal (or pin) 114 that can be coupled to the SCL, a data terminal (or pin) 116 that can be coupled to the SDL, and an alert terminal (pin) 118 that can be coupled to the ALERT #. The secondary bus controller 106 can be coupled to the pins 114-118 and thus can receive bus signals from the host bus controller 104 and communicate bus signals to the host bus controller 104 using the communication bus 112.

The communication bus 112 can be coupled to the voltage source 120 to receive the supply voltage 110, in some instances, using pull-up resistors 166, as shown in FIG. 1. The voltage source 120 can be a direct current (DC) voltage source and thus the supply voltage 110 is a DC voltage. The SDL, SCL and ALERT # of the communication bus 112 can be open-drain (or open-collector) lines. A voltage on the SDL, SCL and ALERT # of the communication bus 112 is a pull-up voltage and can be referred to as a bus voltage. Each pull-up resistor 166 can couple one of the SDL, SCL and ALERT # lines to the voltage source 120 to establish a bus voltage on a respective line. Each pull-up resistor 166 can be used to pull the respective bus line (e.g., the SDL, SCL and ALERT #) of the communication bus 112 to a high bus voltage level when no active communication on the respective bus line is occurring between the host bus controller 104 and the secondary bus controller 106 and to a low bus voltage level when active communication is occurring.

A bus controller (the host bus controller 104 and/or the secondary bus controller 106) drives (pulls) the SDL, SCL, and/or ALERT # to the low bus voltage level to represent a logic low state (0). When the bus controller releases a bus line of the communication bus 112, the bus voltage on the SDL, SCL, and/or ALERT # is pulled back up to the high bus voltage level to represent a logic high state (1). A pulling and releasing of the SDL, SCL, and/or ALERT # line result in generation of bus signals, such as a clock (CLK) signal 122 (identified as “SMB_CLK 122” in FIG. 1), a data input/output (DIO) signal 124 (identified as “SMB_DIO 124” in FIG. 1), and an alert (ALERT) signal 126 (identified as “ALERT 126” in FIG. 1). In some examples, the CLK signal 122 can be referred to as a clock bus signal 122. This alternating pulling (for low) and releasing can produce one or more voltage changes on the bus line corresponding to one or more bus signals that can be provided over the communication bus 112. The one or more bus signals can carry information represented as binary values.

For example, the CLK signal 122 can be generated by the host bus controller 104 (e.g., by manipulating the bus voltage on the SCL to generate alternating logic low and high states) and can be used to synchronize data transmission (e.g., the DIO signal 124) between the host bus controller 104 and the secondary bus controller 106. The host bus controller 104 can provide the CLK signal 122 to the power device 103 at the CLK pin 114 using the SCL of the communication bus 112. In some examples, the CLK pin 114 can be referred to as a bus terminal. The CLK signal 122 can be generated by alternating a voltage level of the bus voltage on the SCL by pulling and releasing the SCL to create logic high and low states representative of logic binary values, such as 1′s and 0's. In a logic high state, the CLK signal 122 is at a high voltage level (e.g., at about the supply voltage 110). In a logic low state, the CLK signal 122 is at a low voltage level (e.g., at about a ground voltage).

The DIO signal 124 is a bidirectional signal that can be transmitted on the SDL and carries data (information) from the secondary bus controller 106 to the host bus controller 104 or vice-versa. In examples in which the DIO signal 124 is generated by the host bus controller 104 (e.g., by manipulating the bus voltage on the SDL to generate logic low and high states to represent information in binary form), the DIO signal 124 can be used to provide data, such as commands, configuration settings, and/or other data to the secondary bus controller 106. In examples in which the DIO signal 124 is generated by the secondary bus controller 106 (e.g., by manipulating the bus voltage on the SDL to generate logic low and high states to represent information in binary form), the DIO signal 124 can include status information, such as operating conditions or responses to commands (e.g., an acknowledgment).

The secondary bus controller 106 can also be configured to generate the ALERT signal 126 (e.g., by manipulating the bus voltage on the ALERT #), which can be provided using the ALERT # to the host bus controller 104. The ALERT signal 126 is a dedicated interrupt signal that can be generated by the secondary bus controller 106 to notify the host bus controller 104 of elevated conditions at the power device 103, such as fault events or warnings (e.g., an overvoltage, an overcurrent, thermal issues, etc.). For example, the secondary bus controller 106 can include an alert generator 184. In some examples, a bus logic 176 of the secondary bus controller 106 can monitor inputs from internal sensors and/or circuits that detect fault conditions, such as overvoltage, overcurrent, or thermal events. When a monitored condition exceeds a predefined threshold, the bus logic 176 signals the alert generator 184 to generate the ALERT signal 126. The alert generator 184 manipulates the bus voltage on the ALERT # line, actively pulling the bus voltage to a low bus voltage level to provide the ALERT signal 126. This change indicates to the host bus controller 104 that a warning or fault condition has occurred. In yet some examples, the alert generator 184 is configured to monitor the operating conditions of the power device 103, such as overvoltage, overcurrent, or thermal issues, and generate the ALERT signal 126 when a fault condition or warning threshold is exceeded. The alert generator 184 manipulates the bus voltage on the ALERT # line by actively pulling the bus voltage to a low bus voltage level to generate the ALERT signal 126 to notify the host bus controller 104 of the detected condition. In some examples, the bus logic 176 includes the functionality of the alert generator 184. Thus, in some examples, the bus logic 176 can manipulate the bus voltage on the ALERT # line to generate the ALERT signal 126.

In some examples, referred to herein as a first example, the voltage source 120 used in the system 100 provides the supply voltage 110 at the low supply voltage level (e.g., at about 1.2V). In the first example, when the secondary bus controller 106 is initialized, the secondary bus controller 106 operates in the LV bus mode (the default bus mode) corresponding to using the LV input voltage threshold. The detector 108 detects that the supply voltage 110 is at the low supply voltage level in response to determining that the bus voltage is at the low bus voltage level, such as on the SCL (clock bus line). The detector 108 allows the secondary bus controller 106 to continue to operate in the LV bus mode in response to determining that the bus voltage is at the low bus voltage level.

In some examples, referred to herein as a second example, the voltage source 120 used in the system 100 provides the supply voltage 110 at the high supply voltage level (e.g., at about 1.8V or 3.3V). The bus voltage on the communication bus 112 is at the high bus voltage level in the second example. The detector 108 detects that the supply voltage 110 is at the high supply voltage level based on the bus voltage being at the high bus voltage level, such as on the SCL (clock bus line). The detector 108 instructs the secondary bus controller 106 to operate in the HV bus mode in response to determining that the bus voltage is at the high bus voltage level.

The secondary bus controller 106 includes input circuit(s) 172, which in some instances, are one or more comparator circuits. The input circuit(s) 172 can include a first input circuit for interpreting a bus signal on the SCL and a second input circuit for interpreting a bus signal on the SDL of the communication bus 112. In some examples, the secondary bus controller 106 can also include memory 174, which can store the bus logic 176 as machine readable instructions, which can be executed by a logic unit (e.g., a controller, a microprocessor, etc.). In some examples, the bus logic 176 corresponds to a bus firmware. In some examples, the bus logic 176 can be implemented as a digital logic circuit.

The bus logic 176 can be used to configure (set) a voltage level that is used as the input voltage threshold 170 (identified as “IN_LOG 170” in FIG. 1) for bus signal interpretation. For example, the bus logic 176 can control the logic level generator 178 to provide the input voltage threshold 170 at a specific voltage level, such as at a first voltage level for an HV bus mode of operation, or at a second voltage level for a LV bus mode of operation. In the first example, the bus logic 176 can instruct the logic level generator 178 to provide the LV input threshold as the input voltage threshold 170. In the second example, the bus logic 176 can instruct the logic level generator 178 to provide the HV input threshold as the input voltage threshold 170.

For example, upon initialization, the bus logic 176 causes the input circuit(s) 172 to use the LV input threshold(s) as the input voltage threshold 170 for bus signal interpretation. Configuring the secondary bus controller 106 (the input circuit(s) 172) to use the LV input threshold upon initialization reduces a likelihood that an initial communication session (also known as an initial PMBus transaction) between the host bus controller 104 and the secondary bus controller 106 fails. This is because at the time of system initialization, noise and other signal integrity concerns are minimal, and the LV input thresholds can be used by the secondary bus controller 106 to reliably interpret initial PMBus packets (for simplicity referred to herein as packets) and establish a PMBus communication (transaction) with the host bus controller 104. The secondary bus controller 106 while operating in the LV bus mode (its default bus mode) can acknowledge the initial packet sent by the host bus controller 104 without disrupting or interrupting the PMBus communication (e.g., causing a PMBus failure).

In some examples, the secondary bus controller 106 is set into a passive waiting mode, such as in response to the secondary bus controller 106 being initialized. In the passive waiting mode, the bus logic 176 monitors the communication bus 112 for communication from the host bus controller 104 indicative of the start of a PMBus transaction (session). Prior to an initial PMBus transaction (session) starting between the host and secondary bus controllers 104-106, the host bus controller 104 is in an idle mode (or state). In the idle state, the host bus controller 104 is not initiating or conducting any communication with the secondary bus controller 106. During this time, the host bus controller 104 is not driving any signals on the communication bus 112 and both the SDL and SCL are held high.

The PMBus transaction (e.g., the initial session) starts when the host bus controller 104 generates a start condition on the communication bus 112. The start condition can be a sequence that occurs on the SDL and SCL to indicate that the host bus controller 104 is about to begin communication. For example, the sequence can include the SDL transitioning from a high voltage level to a low voltage level while the bus voltage on the SCL remains high (at the high bus state). After the start condition is set, the host bus controller 104 can begin generating clock pulses (the CLK signal 122) on the SCL, which can be received at the CLK pin 114 and provided to the secondary bus controller 106 and to the detector 108, as shown in FIG. 1.

During the initial session, one or more initial packets can be transmitted over the SDL, which can be carried by the DIO signal 124. The initial packet can include a group of bits that represent a byte, such as an address byte or a command. The host bus controller 104 initiates and manages the communication process, sending these bytes sequentially, while the secondary bus controller 106 responds based on a command and/or address received. After receiving the initial packet, the bus logic 176 of the secondary bus controller 106 responds with an acknowledgment packet (e.g., ACK), which can be carried by the DIO signal 124, to the host bus controller 104 to confirm successful transmission of the initial packet, completing the initial PMBus transaction. For example, the bus logic 176 of the secondary bus controller 106 can pull the SDL to the low bus voltage level to indicate to the host bus controller 104 that the secondary bus controller 106 has successfully received the initial packet.

For example, during the initial session, the CLK signal 122 can be received from the SCL by the detector 108. The detector 108 can be coupled to the CLK pin 114 to receive the CLK signal 122. The detector 108 includes a bus voltage detector 140. The bus voltage detector 140 can be implemented as a comparator circuit. The bus voltage detector 140 can detect a voltage level (amplitude) of the supply voltage 110 based on a voltage level of a bus voltage (the CLK signal 122) on the communication bus 112 (on the SCL). The bus voltage on the communication bus 112 is based on the supply voltage 110. The CLK signal 122 at a high voltage level represents the bus voltage on the communication bus 112 when at the high bus voltage level. The bus voltage detector 140 can have a first input and a second input, and an output. The first input can be coupled to a bus terminal (the CLK pin 114) and the second input can be coupled to a bus voltage threshold terminal (the bus voltage threshold generator 146).

The bus voltage detector 140 can be configured to compare the bus voltage on the communication bus 112 (the CLK signal 122) to a bus voltage threshold signal 142 (identified as “PMBUS_TH 142” in FIG. 1). The bus voltage threshold signal 142 can be provided by a bus voltage threshold generator 146, as shown in FIG. 1. In a non-limiting example, the bus voltage threshold signal 142 is at about 1.5V. The bus voltage threshold signal 142 can be provided at a bus voltage threshold terminal of the bus voltage threshold generator 146 (or the bus voltage detector 140). The bus voltage threshold generator 146 can be implemented as a voltage divider or as a reference generator. The bus voltage detector 140 can output a bus voltage detected signal 144 (identified as “PMBUS_DET 144” in FIG. 1) based on the comparison. The bus voltage detected signal 144 is indicative of whether the bus voltage on the communication bus 112 is at a high or low bus voltage level.

In the first example, a voltage level (amplitude) of the CLK signal 122 (the bus voltage on the communication bus 112) is below the bus voltage threshold signal 142. As a result, the bus voltage detector 140 does not provide the bus voltage detected signal 144. Thus, in the first example, the bus voltage detected signal 144 is at a low voltage level (e.g., around 0V). The bus voltage on the communication bus 112 is considered low when the supply voltage 110 is at the low supply voltage level (e.g., about 1.2V). In other examples, such as the second example, the bus voltage detector 140 can output the bus voltage detected signal 144 at a high voltage level to indicate that the bus voltage is at the high bus voltage level. The bus voltage on the communication bus 112 is high when the supply voltage 110 is at the high supply voltage level (e.g., about 1.8V or 3.3V).

In some examples, the bus voltage detected signal 144 can be provided to a detector logic 148 (identified as “LOGIC 148” in FIG. 1) to determine whether the secondary bus controller 106 is to operate in the HV bus mode (or continue operating in the LV bus mode). The detector logic 148 can be used to implement (e.g., execute) an auto detection algorithm (for simplicity referred to herein as an algorithm) to initiate auto detection of the bus voltage on the communication bus 112. The algorithm can be used to determine the bus voltage on the communication bus 112 and set a bus operating mode of the secondary bus controller 106 based on the determined bus voltage. For example, in response to determining that the bus voltage on the communication bus 112 is at the high bus voltage level, the algorithm can configure the detector 108 to instruct the secondary bus controller 106 to operate in the HV bus mode.

In some examples, the detector logic 148 can be implemented as a digital logic circuit. In some examples, the detector logic 148 is implemented as a state machine (e.g., a finite state machine). The detector logic 148 can be implemented as hardware, software, and/or a combination thereof. In examples in which the detector logic 148 is implemented as software, the detector logic 148 can be executed by the secondary bus controller 106 (or a different controller on the power device 103). Thus, in some examples, the detector logic 148 can be stored in the memory 174 of the secondary bus controller 106 and executed by the secondary bus controller 106. In yet further examples, the detector logic 148 is part of the bus logic 176, as shown in FIG. 1. In an example, the detector logic 148 is implemented in digital logic (e.g., coded in a hardware description language, such as Verilog code), such as for monitoring signals and setting threshold voltage levels.

For example, the detector logic 148 provides an LV bus mode threshold signal 150 (identified as “LV_TH 150” in FIG. 1) and an HV bus mode threshold signal 152 (identified as “HV_TH 152” in FIG. 1) to a bus mode selector circuit 154. In some examples, the LV bus mode threshold signal 150 can have a voltage level (amplitude or signal magnitude) that is the same as or similar to the HV input threshold (e.g., the second VIH). In yet further examples, the HV bus mode threshold signal 152 can have a voltage level that is the same as or similar to the LV input threshold (e.g., the first VIH).

The bus mode selector circuit 154 can be used to instruct the secondary bus controller 106 to operate in the HV bus mode or allow the secondary bus controller 106 to continue operating in the LV bus mode based on a comparison of one of the LV and HV bus mode threshold signals 150-152 relative to the CLK signal 122. The bus mode selector circuit 154 receives the CLK signal 122, as shown in FIG. 1. The detector logic 148 provides a bus mode threshold select signal 156 (identified as “TH_SEL 156” in FIG. 1) to the bus mode selector circuit 154. The bus mode selector circuit 154 selects one of the LV and HV bus mode threshold signals 150-152 for comparison with the CLK signal 122 to control a bus operating mode of the secondary bus controller 106 based on a voltage level state of the bus mode threshold select signal 156.

For example, such as in the first example, the detector logic 148 can output the bus mode threshold select signal 156 at a first voltage level in response to determining that the bus voltage detected signal 144 is at the high voltage level, indicating that the bus voltage is at the high bus voltage level. In other examples, such as the second example, the detector logic 148 can output the bus mode threshold select signal 156 at a second voltage level (amplitude) in response to not receiving the bus voltage detected signal 144 at the high voltage level. The detector logic 148 determines that the bus voltage is at the low bus voltage level in response to receiving an indication of a successful bus communication 180 (identified as “SUC_BUS 180” in FIG. 1) from the secondary bus controller 106 (or the bus logic 176) while not receiving the bus voltage detected signal 144 at the high voltage level.

In some examples, the bus logic 176 outputs the indication of successful bus communication 180. The bus logic 176 provides the indication of successful bus communication 180 in response to an acknowledgment packet (e.g., a reply packet) being sent to the host bus controller 104. The indication of successful bus communication 180 indicates that a data exchange was successful between the host and secondary bus controllers 104-106 during which the secondary bus controller 106 uses one or more LV input thresholds. In some examples, the bus logic 176 provides the indication of successful bus communication 180 to the detector logic 148 in response to acknowledging the initial packet.

In the second example, the detector logic 148 completes auto detection of the bus voltage on the communication bus 112 in response to receiving the indication of successful bus communication 180 while not receiving the bus voltage detected signal 144 at the high voltage level. The detector logic 148 exits the algorithm corresponding to allowing the secondary bus controller 106 to continue operating in the LV bus mode. For example, the detector logic 148 completes auto detection of the bus voltage on the communication bus 112 by terminating the LV and HV bus mode threshold signals 150-152 from being provided to the bus mode selector circuit 154, which disables this circuit and consequently the detector 108.

In some examples, the bus mode selector circuit 154 includes a clock edge detector 160 and a voltage threshold selector 162. The clock edge detector 160 can be implemented as a flip-flop circuit, such as a D-type flip-flop circuit. The clock edge detector 160 can be configured to detect a clock edge, such as a falling edge, as described herein. The clock edge detector 160 can be configured to store a clock state at each clock pulse and detect transitions from one clock state to another clock state (e.g., from high to low). In some examples, the clock edge detector 160 can be implemented using logic gates (e.g., XOR and AND gates). The voltage threshold selector 162 can be implemented as a multiplexer.

In the first example, the clock edge detector 160 can instruct the secondary bus controller 106 to use the HV input threshold as the input voltage threshold 170. The clock edge detector 160 can instruct the secondary bus controller 106 to use the HV input threshold as the input voltage threshold 170 in response to detecting a falling edge of the CLK signal 122 using the HV bus mode threshold signal 152. For example, when the voltage level of the CLK signal 122 falls below or equals the HV bus mode threshold signal 152, the clock edge detector 160 recognizes this as a falling edge of the CLK signal 122. Upon detecting the falling edge, the clock edge detector 160 generates a bus mode configuration signal 158 (identified as “IO_OUT 158” in FIG. 1). The bus mode configuration signal 158 transitions to a high voltage level (a first voltage amplitude) and is provided to the secondary bus controller 106. The bus logic 176, upon receiving the bus mode configuration signal 158 at the high voltage level, interprets this signal as an instruction to switch its bus operating mode. For example, the bus logic 176 configures the input circuit(s) 172 to use the HV input thresholds (e.g., a higher voltage VIH and VIL) as the input voltage threshold 170 for interpreting bus signals.

In some examples, the detector logic 148 can provide the bus mode threshold select signal 156 at the first or second voltage level to the voltage threshold selector 162 based on a voltage state of the bus voltage detected signal 144. The voltage threshold selector 162 can select one of the LV and HV bus mode threshold signals 150-152 for clock edge detection based on a state of the bus mode threshold select signal 156. The voltage threshold selector 162 is configured to output one of the LV or HV bus mode threshold signals 150-152 as a mode selected threshold signal 164 (identified as “TH_O 164” in FIG. 1) to the clock edge detector 160 based on a voltage level of the bus mode threshold select signal 156.

For example, in the first example, the detector logic 148 can provide the bus mode threshold select signal 156 at the first voltage level to the voltage threshold selector 162, for example, in response to determining (or detecting) that the bus voltage detected signal 144 is at the high voltage level. The voltage threshold selector 162 can provide the HV bus mode threshold signal 152 as the mode selected threshold signal 164 to the clock edge detector 160 in response to receiving the bus mode threshold select signal 156 at the first voltage level.

In other examples, such as the second example, the detector logic 148 can provide the bus mode threshold select signal 156 at the second voltage level to the voltage threshold selector 162, for example, in response to not receiving the bus voltage detected signal 144 at the high voltage level. In the second example, the voltage threshold selector 162 can provide the LV bus mode threshold signal 152 as the mode selected threshold signal 164 to the clock edge detector 160 in response to receiving the bus mode threshold select signal 156 at the second voltage level.

In some examples, such as in the first example, the clock edge detector 160 compares a voltage level (amplitude) of the CLK signal 122 to an amplitude of the HV bus mode threshold signal 152 to detect the falling edge of the CLK signal 122. In the first example, as the CLK signal 122 transitions between a high voltage state (e.g., 1.8V or 3.3V) and a low voltage state (approximately 0V), referred to as a clock edge transition, the clock edge detector 160 detects when the voltage level (amplitude) of the CLK signal 122 drops below (or equals) the amplitude of the HV bus mode threshold signal 152. This drop in the voltage level of the CLK signal 122 (or when the voltage level of the CLK signal 122 equals the HV bus mode threshold signal 152) occurs at the falling edge of the CLK signal 122 during the clock edge transition. In the first example, the clock edge detector 160 outputs the bus mode configuration signal 158 at a high voltage level (a first voltage amplitude) in response to detecting that the voltage level of the CLK signal 122 has fallen below or is equal to the amplitude of the HV bus mode threshold signal 152. The bus mode configuration signal 158 at the high voltage level instructs the secondary bus controller 106 to operate in the HV bus mode corresponding to using the HV input threshold as the input voltage threshold 170.

In the first example, during the initial session, the bus mode configuration signal 158 while at the high voltage level can be provided to the detector logic 148 and to the secondary bus controller 106. The bus logic 176 of the secondary bus controller 106 configures the logic level generator 178 to provide the input voltage threshold 170 as the HV input threshold based on the bus mode configuration signal 158 being at the high voltage level (having the first voltage amplitude). The detector logic 148 completes auto detection of the bus voltage on the communication bus 112 in response to receiving the bus mode configuration signal 158 at the high voltage level (the first voltage amplitude). In some examples, the detector logic 148 completes auto detection of the bus voltage by terminating the LV and HV bus mode threshold signals 150-152 that are provided to the bus mode selector circuit 154 to disable the bus mode selector circuit 154 corresponding to disabling the detector 108.

In some examples, such as in the second example, the clock edge detector 160 compares the voltage level of the CLK signal 122 to the LV bus mode threshold signal 150 that is provided as the mode selected threshold signal 164 to detect the falling edge of the CLK signal 122. However, because a voltage level of the LV bus mode threshold signal 150 is greater than an amplitude (or voltage level) of the CLK signal 122, the clock edge detector 160 does not detect the falling edge of the CLK signal 122 and does not output the bus mode configuration signal 158 at the high voltage level. Instead, in the second example, the bus mode configuration signal 158 is at a low voltage level, such as a second voltage amplitude (e.g., at about 0V). The bus mode configuration signal 158 at the low voltage level does not trigger the secondary bus controller 106 to operate in the HV bus mode.

In some examples, the detector logic 148 can have an input, and first and second outputs. The input of the detector logic 148 can be coupled to the output of the bus voltage detector 140. The bus mode selector circuit 154 can have first, second and third inputs. The first input of the bus mode selector circuit 154 can be coupled to the first output of the detector logic 148. The second input of the bus mode selector circuit 154 can be coupled to the second output of the detector logic 148, and the third input of the bus mode selector circuit 154 can be coupled to the bus terminal (the CLK pin 114). The bus mode selector circuit 154 can include an output that can be coupled to the secondary bus controller 106 and a fourth input that can be coupled to a third output of the detector logic 148. The bus voltage detector 140 is configured to provide at its output the bus voltage detected signal 144 indicative of the bus voltage level of the bus voltage at the bus terminal.

In some examples, the detector logic 148 can be configured to output a first bus mode threshold signal (the LV bus mode threshold signal 150) at the first output of the logic circuit, a second bus mode threshold signal (the HV bus mode threshold signal) at the second output of the logic circuit, and the bus mode threshold select signal 156 at the third output. The bus mode selector circuit 154 is configured to select one of the outputted first and second bus mode threshold signals as the mode selected threshold signal 164 based on a voltage level of the bus mode threshold select signal 156. The bus mode selector circuit 154 is configured to compare the bus voltage level of the bus voltage relative to the mode selected threshold signal 164 to provide the bus mode configuration signal 158 at its output.

In yet some examples, the clock edge detector 160 can include first and second inputs and an output. The output of the clock edge detector 160 can be coupled to the secondary bus controller 106 and the first input of the clock edge detector 160 can be coupled to the bus terminal. The voltage threshold selector 162 can include an output and first, second, and third inputs. The first input of the voltage threshold selector 162 can be coupled to the first output of the detector logic 148. The second output of the voltage threshold selector 162 can be coupled to the second output of the detector logic 148. The third output of the voltage threshold selector 162 can be coupled to the third output of the detector logic 148. The output of the voltage threshold selector 162 can be coupled to the second input of the clock edge detector 160.

In some examples, the voltage threshold selector 162 is configured to receive the output first and second bus mode threshold signals at its respective first and second inputs and the bus mode threshold select signal 156 at its third input. The voltage threshold selector 162 is configured to provide the second bus mode threshold signal at its output in response to receiving the bus mode threshold select signal 156 at the second voltage level.

Accordingly, by configuring the power device 103 with the detector 108, the secondary bus controller 106 can update the input voltage threshold 170 that is used for bus signal interpretation so that the power device 103 can be operated in systems configured with high or low supply voltages. Configuring the power device 103 with the detector 108 allows for a single power device to be used in system design, eliminating a need for system designers to maintain (separate) power devices for LV and HV bus mode scenarios.

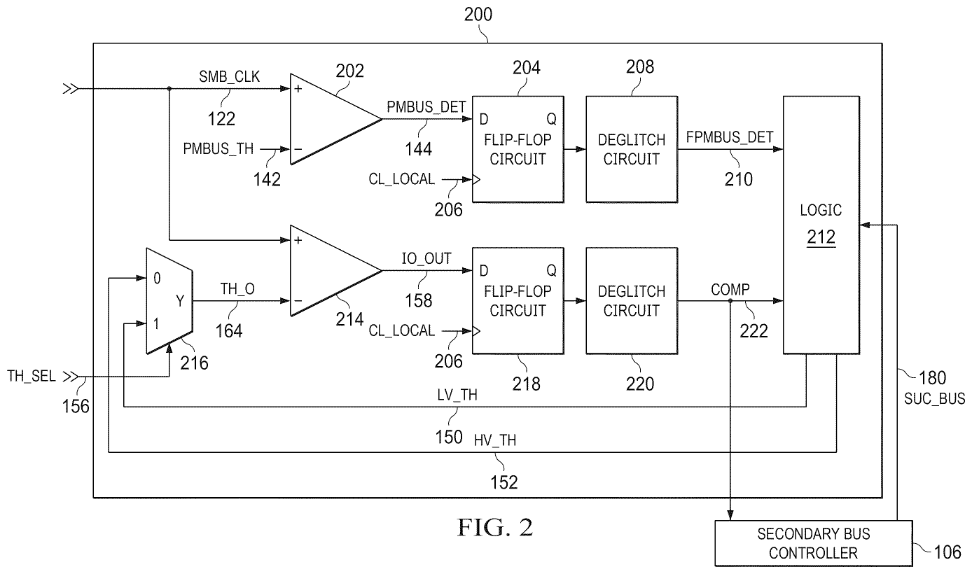

FIG. 2 illustrates an example of a detector 200 (for simplicity referred to herein as a detector 200). In some examples, the detector 200 can be used in the power device 103 as the detector 108 in FIG. 1. For example, the detector 200 can be used to control a bus operating mode of the secondary bus controller 106 based on a bus voltage of the communication bus 112, as shown in FIG. 1. Configuring the power device 103 with the detector 200 enables the secondary bus controller 106 to correctly interpret bus signals on the communication bus 112 at different bus voltage levels (at different supply voltage levels on the communication bus 112). The detector 200 monitors the bus voltage on the communication bus 112, which represents a supply voltage level of the supply voltage 110 being provided by the voltage source 120 to the communication bus 112 to establish a pull-up voltage.

For example, the detector 200 can dynamically configure the secondary bus controller 106 to operate in the HV bus mode in response to determining (detecting) that the bus voltage is at a high bus voltage level (corresponding to the supply voltage 110 being at a high supply voltage level). By using appropriate input voltage thresholds at the secondary bus controller 106 curtails bus signal misinterpretations and reduces communication errors (e.g., misinterpretation of signal logic levels). Furthermore, configuring the power device 103 with the detector 200 eliminates a need to use separate power devices configured for specific voltage modes (e.g., LV or HV), which simplifies system design and avoids potential compatibility issues during system integration. Moreover, the detector 200 can configure the secondary bus controller 106 to operate in the HV bus mode without disrupting a PMBus communication between the host bus controller 104 and the secondary bus controller 106.

The detector 200 includes a bus voltage detector 202, in some instances corresponding to the bus voltage detector 140 of FIG. 1. The bus voltage detector 202 can be implemented as a comparator. The bus voltage detector 202 can receive (at a first input) the CLK signal 122 (identified as “SMB_CLK 122” in FIG. 2) to detect a bus voltage on the SCL of the communication bus 112. The bus voltage on the SCL is a pull-up voltage that is based on the supply voltage 110. Thus, a voltage level of the CLK signal 122 represents the bus voltage of the communication bus 112. The bus voltage detector 202 can receive (at a second input) the bus voltage threshold signal 142 (identified as “PMBUS_TH 142” in FIG. 2), which can be provided by the bus voltage threshold generator 146 of FIG. 1.

The bus voltage detector 202 can provide (at an output) the bus voltage detected signal 144 (identified as “PMBUS_DET 144” in FIG. 2) at a high voltage level to indicate that the bus voltage on the communication bus 112 is at a high bus voltage level. The bus voltage detector 202 provides the bus voltage detected signal 144 in response to the voltage level of the CLK signal 122 (the bus voltage on the communication bus 112) being greater than the bus voltage threshold signal 142. In other examples, the bus voltage detector 202 does not provide the bus voltage detected signal 144 at the high voltage level, which indicates that the voltage level of the bus voltage on the communication bus 112 is at a low bus voltage level. The bus voltage detector 202 does not provide the bus voltage detected signal 144 at the high voltage level when the voltage level of the CLK signal 122 (the bus voltage on the communication bus 112) is not greater than (or equal to) the bus voltage threshold signal 142.

The detector 200 includes a first flip-flop circuit 204, which can be a D-type flip-flop. The first flip-flop circuit 204 includes a data input (identified as “D” in FIG. 2) to capture the bus voltage detected signal 144 at the high voltage level, and a clock input, at which a local CLK signal 206 (identified as “CL_LOCAL 206” in FIG. 2) can be received. The local CLK signal 206 can be generated by a local clock generator of the power device 103 or the secondary bus controller 106. The local CLK signal 206 can have a greater clock frequency than a bus clock signal, the CLK signal 122. For example, the local CLK signal 206 can be a 100 Megahertz (MHz) clock signal whereas the CLK signal 122 can be a 1 MHz clock signal.

The first flip-flop circuit 204 captures the bus voltage detected signal 144 on a rising (or falling) edge of the local CLK signal 206 and holds (latches) this signal until a next clock event. The first flip-flop circuit 204 can provide at an output (identified as “Q” in FIG. 2) a latched bus voltage detected signal that is based on a voltage state of the bus voltage detected signal 144. The latched bus voltage detected signal can be provided to a first deglitch circuit 208 of the detector 200.

The first deglitch circuit 208 can be used to curtail (or filter) transient glitches (e.g., noise, short duration voltages spikes in the latched bus voltage detected signal, etc.). The first deglitch circuit 208 can be configured to introduce a delay period to reduce transient glitches in the latched bus voltage detected signal (if any). In some examples, the delay period is 50 milliseconds (ms). The first deglitch circuit 208 can provide a filtered bus voltage detected signal 210 (identified as “FPBUS_DET 212” in FIG. 2) to a detector logic 212 of the detector 200 (referred to as “LOGIC 212” in FIG. 2). In some examples, the detector logic 212 corresponds to the detector logic 148 of FIG. 1. Thus, the detector logic 212 can be implemented in a same or similar manner as the detector logic 148. By way of example, the detector logic 212 can be implemented in digital logic (e.g., coded in a hardware description language, such as Verilog code), such as for example, for monitoring signals and setting threshold voltage levels.

The filtered bus voltage detected signal 210 can be provided to detector logic 212. The detector logic 212 can be used to implement (e.g., execute) an auto detection algorithm (for simplicity referred to herein as an algorithm) to initiate auto detection of the bus voltage on the communication bus 112. The algorithm can be used to (automatically) detect the bus voltage on the communication bus 112 and set a bus operating mode of the secondary bus controller 106 based on the detected bus voltage.

The detector logic 212 (the algorithm) can allow the secondary bus controller 106 to continue operating the LV bus mode or instruct the secondary bus controller 106 to operate in the HV bus mode based on the filtered bus voltage detected signal 210. For example, in response to the initialization of the detector 200, the detector logic 212 provides the LV bus mode threshold signal 150 (identified as “LV_TH 150” in FIG. 2) and the HV bus mode threshold signal 152 (identified as “HV_TH 152” in FIG. 2) to a voltage threshold selector 216 of the detector 200. In some examples, the voltage threshold selector 216 corresponds to the voltage threshold selector 162 of FIG. 1.

The detector logic 212 provides the bus mode threshold select signal 156 (identified as “TH_SEL 156” in FIG. 2) to the voltage threshold selector 216. The voltage threshold selector 216 selects one of the LV and HV bus mode threshold signals 150-152 based on a voltage level state of the bus mode threshold select signal 156 in a same or similar manner as the voltage threshold selector 162, as described herein, to provide a mode selected threshold signal 164 (identified as “TH_O 164” in FIG. 1). The detector 200 further includes a clock edge detector 214, which can be implemented, in some instances, as a comparator. The clock edge detector 214 can be an example of the clock edge detector 160 of FIG. 1. The clock edge detector 214 can receive the mode selected threshold signal 164.

In some scenarios, such as in the first example, the detector logic 212 outputs the bus mode threshold select signal 156 at a first voltage level when the bus voltage detected signal 144 (the filtered bus voltage detected signal 210) indicates a high bus voltage level. In other scenarios, such as the second example, the detector logic 212 outputs the bus mode threshold select signal 156 at a second voltage level in response to not receiving the bus voltage detected signal 144 (the filtered bus voltage detected signal 210) at a high bus voltage level. In the second example, the bus voltage detected signal 144 is at a low bus voltage level (e.g., at about 0V).

The voltage threshold selector 216 selects between HV and LV bus mode threshold signals 150-152 based on the bus mode threshold select signal 156 to provide a selected bus mode threshold signal as the mode selected threshold signal 164 to the clock edge detector 214. The mode selected threshold signal 164 can be provided by the voltage threshold selector 216 based on a state of the bus mode threshold select signal 156, which can determine whether the HV or LV bus mode threshold signal 150-152 is selected for output. The clock edge detector 214 then monitors for a clock edge transition on the CLK signal 122 using the selected threshold signal (the mode selected threshold signal 164) in a same or similar manner as described herein with respect to the clock edge detector 160 to provide the bus mode configuration signal 158 (identified as “IO_OUT 158” in FIG. 2) at a high voltage level. The bus mode configuration signal 158, when provided at the high voltage level, instructs the secondary bus controller 106 to operate in the HV bus mode.

For example, in the first example, the voltage threshold selector 216 can provide the HV bus mode threshold signal 152 as the mode selected threshold signal 164 to the clock edge detector 214 in response to receiving the bus mode threshold select signal 156 at the first voltage level from the detector logic 212. In the second example, the voltage threshold selector 216 can provide the HV bus mode threshold signal 152 as the mode selected threshold signal 164 to the clock edge detector 214 in response to receiving the bus mode threshold select signal 156 at the second voltage level from the detector logic 212.

In some scenarios, such as in the first example, the clock edge detector 214 compares the voltage level of the CLK signal 122 to the mode selected threshold signal 164, which is set by the voltage threshold selector 216 to either the HV bus mode threshold signal 152 or the LV bus mode threshold signal 150 based on the state of the bus mode threshold select signal 156. The clock edge detector 214 outputs the bus mode configuration signal 158 at a high voltage level in response to detecting that the voltage level of the CLK signal 122 has fallen below or is equal to the mode selected threshold signal 164.

In the second example, the clock edge detector 214 compares the voltage level of the CLK signal 122 to the LV bus mode threshold signal 150 to detect the falling edge of the CLK signal 122. Because a voltage level of the LV bus mode threshold signal 150 is greater than the high voltage level of the CLK signal 122 in the second example, the clock edge detector 214 does not detect the falling edge of the CLK signal 122 and does not output the bus mode configuration signal 158 at the high voltage level. In the second example, the bus mode configuration signal 158 is at a low voltage level (e.g., at about 0V).

The detector 200 includes a second flip-flop circuit 218 (a D-type flip-flop, in some instances) and a second deglitch circuit 220. The second flip-flop circuit 218 includes a data input (identified as “D” in FIG. 2) to capture the bus mode configuration signal 158 at the high voltage level, and a clock input, at which the local CLK signal 206 can be received. The second flip-flop circuit 218 captures the bus mode configuration signal 158 when at the high voltage level on a rising (or falling) edge of the local CLK signal 206 and holds (this signal until a next clock event.

The second flip-flop circuit 218 can provide at an output (identified as “Q” in FIG. 2) a latched bus mode configuration signal that can be based on a voltage state (the high voltage state) of the bus mode configuration signal 158. The latched bus mode configuration signal can be provided to the second deglitch circuit 220. The second deglitch circuit 220 can be used to curtail (or filter) transient glitches (e.g., noise, short duration voltages spikes in the latched bus mode configuration signal). The second deglitch circuit 220 can introduce a delay period to curtail the transient glitches (if any) in the latched bus mode configuration. In some examples, the delay period of the second deglitch circuit 220 is 50 ms. The second deglitch circuit 220 can provide a COMP signal 222 (identified as “COMP 222” in FIG. 2) based on the latched bus mode configuration signal.

The COMP signal 222 can be provided to the secondary bus controller 106. The COMP signal 222 has a voltage level (amplitude) commensurate with (e.g., same or similar to) a voltage level of the bus mode configuration signal 158. In some examples, such as in the first example, the COMP signal 222 is at a high voltage level, which can indicate to the secondary bus controller to operate in the HV bus mode.

In the first example, the COMP signal 222 when at the high voltage level can be provided to the detector logic 212 and the secondary bus controller 106. The bus logic 176 of the secondary bus controller 106 controls the logic level generator 178 to provide the input voltage threshold 170 corresponding to the HV input threshold to the input circuit 172 in response to receiving the COMP signal 222 at the high voltage level. The detector logic 212 completes auto detection of the bus voltage on the communication bus 112 in response to receiving the COMP signal 222 at the high voltage level. In some examples, the detector logic 212 completes auto detection of the bus voltage on the communication bus 112. In response to terminating the LV and HV bus mode threshold signals 150-152 from being delivered to the voltage threshold selector 216 turns off the detector 200.

In some examples, such as in the second example, the clock edge detector 160 compares the voltage level of the CLK signal 122 to the LV bus mode threshold signal 150 to detect the falling edge of the CLK signal 122. Because a voltage level of the LV bus mode threshold signal 150 is greater than the high voltage level of the CLK signal 122, the clock edge detector 160 does not detect the falling edge of the CLK signal 122 and does not output the bus mode configuration signal 158 at the high voltage level. As such, the bus mode configuration signal 158 is not provided at the high voltage level in the second example to the secondary bus controller 106 and the secondary bus controller 106 continues to operate in the LV bus mode.

In some examples, the bus logic 176 causes the secondary bus controller 106 (or the bus logic 176) to output an indication of successful bus communication 180 (identified as “SUC_BUS 180” in FIG. 2). The indication of successful bus communication 180 can be provided in response to sending an acknowledgment packet (e.g., a reply packet) to the host bus controller 104 according to one or more examples as described herein (e.g., with respect to FIG. 1). In some examples, the bus logic 176 can provide the indication of successful bus communication 180 to the detector logic 212 during an initial communication session, such as described herein.

In the second example, the detector logic 212 completes auto detection of the bus voltage on the communication bus 112 in response to receiving the indication of successful bus communication 180 while not receiving the bus voltage detected signal 144 at the high voltage level. In some examples, the detector logic 212 completes auto detection of the bus voltage on the communication bus 112 by terminating the LV and HV bus mode threshold signals 150-152 that are provided to the voltage threshold selector 216 in response to receiving the indication of successful bus communication 180. Terminating the LV and HV bus mode threshold signals 150-152 from being delivered to the voltage threshold selector 216 turns off the detector 200.

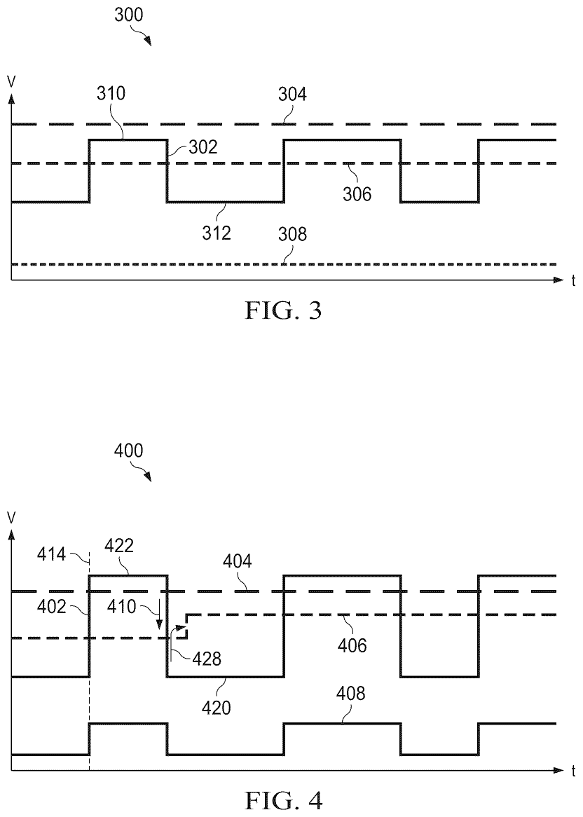

FIG. 3 illustrates an example of a waveform diagram 300 associated with an LV operating bus mode of a detector, such as the detector 108 of FIG. 1 or the detector 200 of FIG. 2. The waveform diagram 300 illustrates the operation of the detector 108, 200 in which the power device 103 is used in the first example of the system 100 (e.g., when the supply voltage 110 is at the low supply voltage level (e.g., at about 1.2V)).

The waveform diagram 300 includes a CLK signal 302 (e.g., the CLK signal 122 of FIGS. 1-2), a bus voltage threshold signal 304 (e.g., the bus voltage threshold signal 142 of FIGS. 1-2), an input voltage threshold indicator 306, and a bus voltage detected signal 308 (e.g., the bus voltage detected signal 144 of FIGS. 1-2). In a non-limiting example, the CLK signal 302 can have a voltage level of about 1.2V. For example, in response to the initialization of the secondary bus controller 106, the bus logic 176 configures the secondary bus controller 106 to operate in the LV bus mode (its default bus mode) corresponding to setting the input circuit(s) 172 to use an LV input threshold(s) as the input voltage threshold indicator 306. The input voltage threshold indicator 306 represents a voltage threshold that is being used by the secondary bus controller 106. Thus, the input voltage threshold indicator 306 represents whether the secondary bus controller 106 is using the LV or HV input threshold.

The bus voltage threshold generator 146 generates the bus voltage threshold signal 304 in response to the power device 103 (or the secondary bus controller 106) being powered. The bus voltage threshold signal 304 can have a voltage level of about 1.5V. The detector 108, 200 receives the CLK signal 302, as shown in FIG. 3, for example, in response to an initial communication session (transaction) between the host and secondary bus controllers 104-106. The bus voltage detector 140, 202 compares a voltage level of the CLK signal 302 to the bus voltage threshold signal 304 to detect an amount of supply voltage (the supply voltage 110) being provided (supplied) by the voltage source 120 to the communication bus 112.

The bus voltage detector 140, 202 determines (detects) the voltage level of the supply voltage 110 based on a voltage level of the bus voltage on the communication bus 112 (as represented by the voltage level of the CLK signal 302). For example, the bus voltage detector 140, 202 can detect the voltage level of the bus voltage on the communication bus 112 based on an amplitude (voltage level) of the CLK signal 302. The bus voltage detector 140, 202 does not generate the bus voltage detected signal 308 at a high voltage level when an amplitude (or voltage level) 310 of the CLK signal 302 is less than the bus voltage threshold signal 304. In the first example, the bus voltage detected signal 308 is at a low voltage level (e.g., at about 0V), which indicates that a bus voltage on the communication bus 112 is at a low bus voltage level.

For example, the detector logic 148, 212 of the detector 108, 200 can be configured to execute an auto detection algorithm to initiate auto detection of the bus voltage on the communication bus 112, such as described herein. The algorithm can be used to (automatically) detect the bus voltage on the communication bus 112 and control a bus operating mode of the secondary bus controller 106 based on the detected bus voltage in response to the detector 108 being initialized. In some examples, while the secondary bus controller 106 is operating in the LV bus mode, the detector logic 148, 212 (the algorithm) receives the indication of successful bus communication 180, as illustrated in FIGS. 1-2, for example, in response to sending an acknowledgment packet (e.g., a reply packet) to the host bus controller 104 during the initial communication session.

The algorithm determines that the secondary bus controller 106 is to continue operating the LV bus mode in response to receiving the indication of successful bus communication 180 while not receiving the bus voltage detected signal 308 at the high voltage level. The detector logic 148, 212 completes auto detection of the bus voltage on the communication bus 112 algorithm in response to receiving the indication of successful bus communication 180 while not receiving the bus voltage detected signal 308 at the high voltage level.

FIG. 4 illustrates an example of a waveform diagram 400 associated with an HV bus operating mode of a detector, such as the detector 108 of FIG. 1 or the detector 200 of FIG. 2. The waveform diagram 400 illustrates the operation of the detector 108, 200 in which the power device 103 is used in the second example of the system 100 (e.g., when the supply voltage 110 is at the high supply voltage level (e.g., at about 1.8V or 3.3V)).

The waveform diagram 400 includes a CLK signal 402 (e.g., the CLK signal 122 of FIGS. 1-2), the bus voltage threshold signal 404 (e.g., the bus voltage threshold signal 142 of FIGS. 1-2), an input voltage threshold indicator 406, and a bus voltage detected signal 408 (e.g., the bus voltage detected signal 144 of FIGS. 1-2). In a non-limiting example, the CLK signal 302 can have a voltage level of about 1.8V. The input voltage threshold indicator 406 represents a voltage threshold that is being used by the secondary bus controller 106. Thus, the input voltage threshold indicator 406 indicates whether the secondary bus controller 106 is using an LV or HV input threshold.

For example, in response to the initialization of the secondary bus controller 106, the bus logic 176 configures the secondary bus controller 106 to operate in the LV bus mode (its default bus mode) corresponding to the input circuit(s) 172 using the LV input threshold(s). The secondary bus controller 106 continuing to use the LV input threshold is represented in the waveform diagram 300 with the input voltage threshold indicator 306 maintaining its current input voltage threshold state (or not changing). In response to the initialization of the host device 102, the host bus controller 104 can start an initial communication transaction (session) with the secondary bus controller 106.

The bus voltage threshold generator 146 generates the bus voltage threshold signal 404 in response to the power device 103 being powered. The bus voltage threshold signal 404 can have a voltage level of about 1.5V. The detector 108, 200 receives the CLK signal 402, as shown in FIG. 4 in response to the initial communication transaction. Because the communication bus 112 receives the supply voltage 110 at a high supply voltage level, the CLK signal 402 has a greater amplitude (voltage level) in FIG. 4 in contrast to the CLK signal 302 in FIG. 3, where the supply voltage 110 is provided at a low supply voltage level.

The bus voltage detector 140, 202 compares a voltage level of the CLK signal 402 to the bus voltage threshold signal 404 to detect an amount of supply voltage (the supply voltage 110) being provided (supplied) by the voltage source 120 to the communication bus 112. The bus voltage detector 140, 202 determines (detect) the voltage level of the supply voltage 110 based on a voltage level of the bus voltage on the communication bus 112 (as represented by the voltage level of the CLK signal 402).

The bus voltage detector 140, 202 determines that the CLK signal 402 is in a logic high state, such as a time 414. At the time 414, the bus voltage detector 140, 202 determines that the voltage level of the CLK signal 402 is greater than (or equal to) the bus voltage threshold signal 404. The bus voltage detector 140, 202 outputs the bus voltage detected signal 408 at a high voltage level in response to determining that the high voltage level of the CLK signal 402 is greater than (or equal to) the bus voltage threshold signal 404.

The bus voltage detected signal 408 at the high voltage level is provided to the detector logic 148, 212. The detector logic 148, 212 of the detector 108, 200 executes an auto detection algorithm to initiate auto detection of the bus voltage on the communication bus 112. The algorithm can be used to (automatically) detect the bus voltage on the communication bus 112 and set a bus operating mode of the secondary bus controller 106 based on the detected bus voltage. For example, the algorithm can cause detector 108, 200 to detect a falling edge 410 of the CLK signal 402 to instruct the secondary bus controller 106 to operate in the HV bus mode according to one or more examples as described herein. For example, in response to detecting the falling edge 410 of the CLK signal 402, the detector 108, 200 can instruct the secondary bus controller 106 to operate in the HV bus mode (and thus use the HV input threshold as the input voltage threshold 170) according to one or more examples herein.

As illustrated in FIG. 4, each clock cycle of the CLK signal 402 has a logic low state 420 at which the CLK signal 402 is at the low voltage level and a logic high state 422 at which the CLK signal 402 is at the high voltage level. The logic low state 420 of the CLK signal 402 can have a minimum time length that provides sufficient time for the secondary bus controller 106 to be configured to use the HV input threshold as the input voltage threshold 170.

For example, in response to detecting the falling edge 410 of the CLK signal 402, during the logic low state 420 of the CLK signal 402, the detector 108, 200, is configured to instruct the secondary bus controller 106 to switch to using the HV input threshold from the LV input threshold for bus signal interpretation, which is illustrated in FIG. 4 as the input voltage threshold indicator 406 transitioning at 428 from a first input voltage threshold state to a second input voltage threshold.

In some examples, the detector 108 provides the bus mode configuration signal 158 at a high voltage level to the secondary bus controller 106 to indicate to the secondary bus controller 106 to operate in the HV bus mode and thus use the HV input threshold. In some examples, the detector 200 provides the COMP signal 222 at a high voltage level to the secondary bus controller 106 to indicate to the secondary bus controller 106 to operate in the HV bus mode and thus use the HV input threshold. The detector logic 148, 212 completes auto detection of the bus voltage on the communication bus 112 in response to receiving the bus mode configuration signal 158 or the COMP signal 22 at the high voltage level.

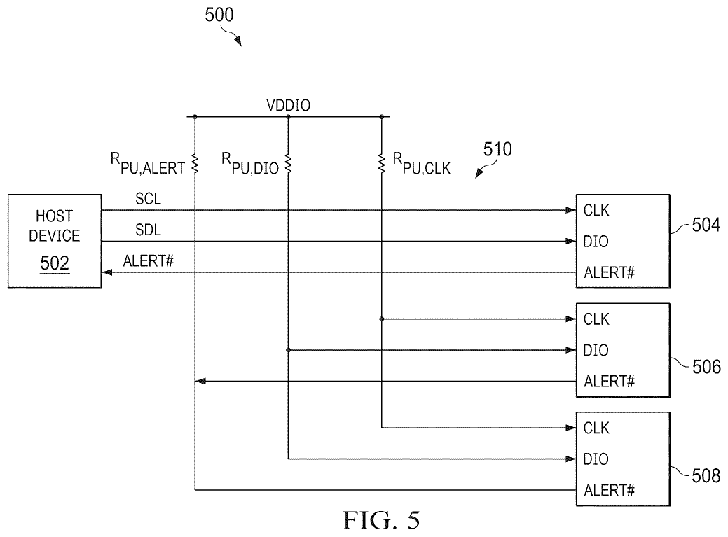

FIG. 5 is an example of a system 500. The system 500 includes a host device 502 and a plurality of power devices 504-508 (e.g., power management devices). In some examples, the host device 502 is the host device 102 of FIG. 1. One or more power devices 504-508 can be configured with a detector, such as the detector 108 of FIG. 1 or the detector 200 of FIG. 2. In some examples, not all of the power devices 504-508 are implemented with the detector 108 or 200.

The host device 502 can be coupled to the power devices 504-508 using a communication bus 510, which can be implemented similarly to the communication bus 112 of FIG. 1. The communication bus 510 includes an SCL, SDL, and ALERT #. Each of the power devices 504-508 includes a CLK pin (identified as “CLK” in FIG. 5), a DIO pin (identified as “DIO” in FIG. 5), and an ALERT pin (identified as “ALERT #” in FIG. 5). The CLK pin of the power devices 504-508 can be coupled to the SCL, the DIO pin of the power devices 504-508 can be coupled to the SDL, and the ALERT pin of the power devices 504-508 can be coupled to the ALERT #.

As shown in FIG. 5, each bus line of the communication bus 510 can be coupled to a pull-up resistor to receive a supply voltage (e.g., the supply voltage 110 of FIG. 1) to establish a pull-voltage on each signal line, referred to as a bus voltage. The supply voltage is identified as “VDDIO” in FIG. 5 and can be provided by a voltage source, such as the voltage source 120 of FIG. 1. In the example of FIG. 5, the supply voltage is provided by the voltage source at a high supply voltage level (e.g., 1.8V or 3.3V). A pull-up resistor R_{PU,CLK} can be used to establish the bus voltage on the SCL based on the supply voltage. A pull-up resistor R_{PU,DIO} can be used to establish the bus voltage on the SDL based on the supply voltage. A pull-up resistor R_{PU,ALERT} can be used to establish the bus voltage on the ALERT # based on the supply voltage.

In some examples, in response to the power devices 504-508 being powered, each power device that is configured with the detector 108, 200 can enter a default bus mode, an LV bus mode. The detector 108, 200 can be configured to detect that a voltage level of the bus voltage on the communication bus 510 according to the examples herein. The detector 108, 200 can instruct a bus controller of each power device that is configured with the detector 108 or 200 to operate in an HV bus mode in response to detecting an elevated bus voltage on the communication bus 112, such as when the bus voltage is at a high bus voltage level. Accordingly, each power device that is configured with the detector 108, 200 in the example of FIG. 5 can automatically instruct a corresponding bus controller to use appropriate input logic level thresholds (e.g., one or more HV input thresholds) so that bus signals transmitted by the host device 502 can be correctly interpreted.

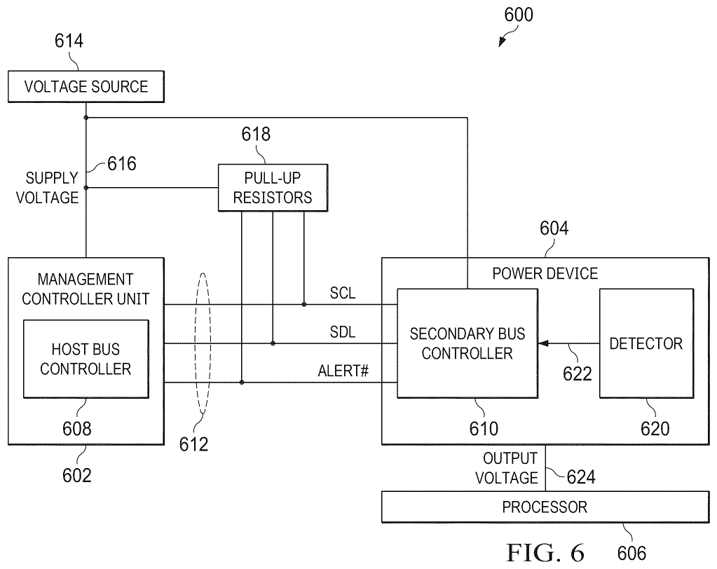

FIG. 6 illustrates an example of a system 600. The system 600 includes a management control unit (MCU) 602 and a power device 604 (e.g., a power management device). In some examples, the system 600 can be implemented on a printed circuit board (PCB). In some examples, the PCB is a motherboard, such as a server motherboard and thus the system 600 can be implemented on the motherboard. The MCU 602 can be used to control an output voltage 624 being provided by the power device 604 to a processor 606. In some examples, the MCU 602 is a board management controller. In yet further examples, the MCU 602 can be an example of the host device 102 of FIG. 1 and the power device 604 can be an example of the power device 103 of FIG. 1.

The MCU 602 can be coupled to the power device 604 using a communication bus 612 that includes an SCL for transmitting CLK signals (e.g., the CLK signal 122 of FIG. 1), an SDL for transmitting DIO signals (e.g., the DIO signal 124 of FIG. 1) and an ALERT # for transmitting the ALERT signals (e.g., the ALERT signal 126 of FIG. 1). The MCU 602 includes a host bus controller 608 (e.g., the host bus controller 104 of FIG. 1) and the power device 604 includes a secondary bus controller 610 (e.g., the secondary bus controller 106 of FIG. 1) so that the MCU 602 and the power device 604 can exchange information (or data). The host bus controller 608 and the secondary bus controller 610 can communicate using a PMBus protocol. The host bus controller 608 can send one or more commands, data, addresses, and/or other data to the secondary bus controller 610 according to a PMBus protocol (specification). For example, the host bus controller 608 can send a bus command to the power device 604.

The communication bus 612 is coupled to a voltage source 614 (e.g., the voltage source 120 of FIG. 1) using pull-up resistors 618 (e.g., the pull-up resistors 166 of FIG. 1) to establish a bus voltage on each bus line (e.g., the SCL, SDL and ALERT #). The voltage source 614 can output a supply voltage 616. A pull-up resistor of the pull-up resistors 618 can couple each bus line of the communication bus 612 to the voltage source 614. The supply voltage 616 can be provided to the MCU 602 to power the host bus controller 608. In the example of FIG. 6, the supply voltage 616 being provided is at a high voltage level (e.g., 1.8V or 3.3V). The supply voltage 616 can be provided to the power device 604, for example, to the secondary bus controller 610 to power one or more components of the secondary bus controller 610.

The power device 604 includes a detector 620 to detect the bus voltage on the communication bus 612. The detected bus voltage on the communication bus 612 can be used to set a bus operating mode of the secondary bus controller 610 according to one or more examples herein. The detector 620 can be an example of the detector 108 of FIG. 1 or the detector 200 of FIG. 2. For example, in response to being powered, the host bus controller 608 starts an initial communication transaction (session) with the power device 604.

Upon initialization of the secondary bus controller 610 (e.g., in response to being powered), the secondary bus controller 610 operates in a default bus mode, an LV bus mode. In the LV bus mode, the secondary bus controller 610 uses one or more LV thresholds for interpreting bus signals communicated by the host bus controller 608. During the initial communication transaction, the host bus controller 608 communicates one or more bus signals carrying one or more initial packets. The secondary bus controller 610 sends a response packet to the host bus controller 608 to acknowledge that the secondary bus controller 610 has received the initial packet so that a communication session between the host and secondary bus controllers 608-610 is not disrupted or interrupted.

In response to the secondary bus controller 610 being initialized, the detector 620 detects a bus voltage on the communication bus 612 (e.g., on the SCL line) according to one or more examples herein. The detector 620 outputs a bus mode configuration signal 622 to instruct the secondary bus controller 610 to operate in the HV bus mode corresponding to using one or more HV input thresholds for bus signal interpretation according to one or more examples herein. In some examples, the bus mode configuration signal 622 is the bus mode configuration signal 158 of FIG. 1 or the COMP signal 222 of FIG. 2.

In some examples, such as after the initial communication transaction, during a subsequent communication transaction, the host bus controller 608 sends a bus command as a DIO signal on the SDL of the communication bus 612. The bus command can be used to instruct the power device 604 to provide the output voltage 624 to the processor 606. The secondary bus controller 610 uses one or more HV thresholds to interpret the DIO signal to extract the bus command. The power device 604 (e.g., another controller on the power device 604 or the secondary bus controller 610) can process the bus command, for example, to provide the output voltage 624 at a specified voltage level (amplitude) to the processor 606.

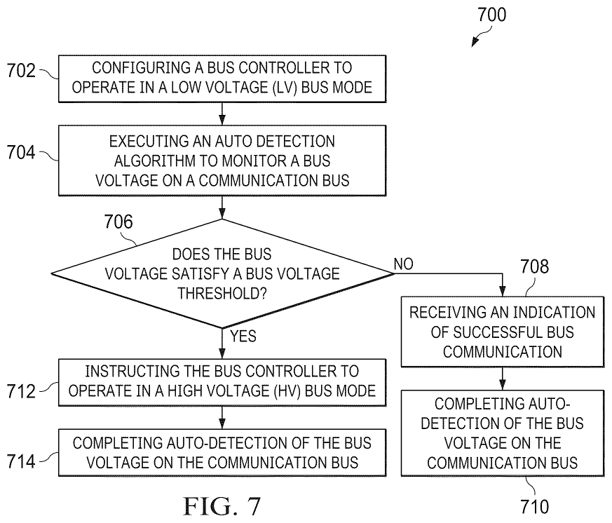

FIG. 7 illustrates a flowchart of an example method 700 for controlling a bus operating mode of a bus controller, such as the secondary bus controller 106 of FIGS. 1-2 or the secondary bus controller 610 of FIG. 1. One or more steps of the method 700 can be implemented by a communication bus detector, such as the detector 108 of FIG. 1, the detector 200 of FIG. 2, or the detector 620 of FIG. 6. For example, one or more steps of the method 700 can be implemented by the detector logic 148 of FIG. 1 or the detector logic 212 of FIG. 2. Although the flowchart illustrates the method 700 in a particular order, the steps can be rearranged, some steps can be performed in parallel, and others can be omitted entirely.

The method 700 can begin at block 702, with the secondary bus controller 106, 610 being configured to operate in an LV bus mode according to one or more examples, as described herein. For example, the bus logic 176 can configure the input circuit(s) 172 to use the LV input threshold(s). In the LV bus mode, the input circuit(s) 172 of the secondary bus controller 106, 610 use one or more LV input thresholds for bus signal interpretation corresponding to operating the secondary bus controller 106, 610 in the LV bus mode. The secondary bus controller 106, 610 is configured to operate in the LV bus mode in response to a power device (e.g., the power device 103 of FIG. 1) being initialized (e.g., being powered).

At block 704, the detector logic 148, 212 executes an auto detection algorithm to initiate auto detection of a bus voltage on a communication bus, for example, in response to the power device being initialized. During auto detection, the detector logic 148, 212 monitors (e.g., polls or samples) the bus voltage on the communication bus. For example, the communication bus corresponds to the communication bus 112 of FIG. 1 or the communication bus 612 of FIG. 6.

At block 706, the detector logic 148, 212 determines whether the bus voltage (e.g., a bus signal, such as the CLK signal 122 of FIG. 1) on the communication bus has satisfied a bus voltage threshold signal (e.g., the bus voltage threshold signal 142 of FIGS. 1-2). The method 700 proceeds from block 706 to block 704 in response to the detector logic 148, 212 determining that the communication bus voltage has not satisfied the bus voltage threshold signal (shown as a “NO” in FIG. 7). The bus voltage does not satisfy the bus voltage threshold signal when a bus voltage detected signal (e.g., the bus voltage detected signal 144 of FIGS. 1-2) is at a low voltage level (e.g., at about 0V).

At block 708, the detector logic 148, 212 receives an indication of successful bus communication (e.g., the indication of successful bus communication 180 of FIGS. 1-2) while the bus voltage detected signal is at the low voltage level. The indication of successful bus communication can be provided by the bus logic 176 to the detector logic 148, 212. At block 710, the detector logic 148, 212 completes the auto detection of the bus voltage on the communication bus (e.g., execution of the auto detection algorithm) in response to receiving an indication of successful bus communication while the bus voltage detected signal is at the low voltage level.

In some examples, method 700 proceeds from block 706 to block 712 in response to the detector logic 148, 212 determining that the communication bus voltage satisfies the bus voltage threshold signal (shown as a “YES” in FIG. 7). The bus voltage satisfies the bus voltage threshold signal when the bus voltage detected signal is at a high voltage level. The bus voltage detected signal is at the high voltage level when the bus voltage is greater than or equal to the bus voltage threshold signal.

At block 712, the detector logic 148, 212 instructs the secondary bus controller 106, 610 to operate in an HV bus mode in response to the bus voltage detected signal being at the high voltage level. For example, the detector logic 148, 212 can configure the detector 108, 200, 620 to detect a signal edge transition of the bus voltage. The detector 108, 200, 620 can detect a falling edge of the bus voltage according to one or more examples, as described herein. The detector 108, 200, 620 communicates a bus mode configuration signal (e.g., bus mode configuration signal 158 of FIG. 1, the COMP signal 222 of FIG. 2 or the bus mode configuration signal 622 of FIG. 6) at a high voltage level to the secondary bus controller 106, 610 to instruct to the secondary bus controller 106, 610 to operate in the HV bus mode in response to detecting the signal edge transition according to one or more examples herein. The bus logic 176 of the secondary bus controller 106, 610 causes the input circuit(s) 172 to use one or more HV input thresholds for bus signal interpretation corresponding to operating the secondary bus controller 106, 610 in the HV bus mode.

At block 714, the detector logic 148, 212 completes the auto detection of the bus voltage on the communication bus (e.g., execution of the auto detection algorithm) in response to instructing the secondary bus controller 106, 610 to operate in the HV bus mode. For example, the detector logic 148, 212 completes the auto detection of the bus voltage on the communication bus in response to determining that the bus mode configuration signal is at the high voltage level (e.g., a high logic state).

In this description, numerical designations “first”, “second”, etc. are not necessarily consistent with same designations in the claims herein. Additionally, the term “couple” or variants thereof may cover connections, communications, or signal paths that enable a functional relationship consistent with this description. For example, if device A generates a signal to control device B to perform an action, then: (a) in a first example, device A is directly coupled to device B; or (b) in a second example, device A is indirectly coupled to device B through intervening component C if intervening component C does not alter the functional relationship between device A and device B, so device B is controlled by device A via the control signal generated by device A. In this description, the term “based on” means based at least in part on.

Also, in this description, a device that is “configured to” perform a task or function may be configured (e.g., programmed and/or hardwired) at a time of manufacturing by a manufacturer to perform the function and/or may be configurable (or reconfigurable) by a user after manufacturing to perform the function and/or other additional or alternative functions. The configuring may be through firmware and/or software programming of the device, through a construction and/or layout of hardware components and interconnections of the device, or a combination thereof.

Furthermore, a circuit or device described herein as including certain components may instead be configured to couple to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor wafer and/or integrated circuit (IC) package) and may be configured to couple to at least some of the passive elements and/or the sources to form the described structure, either at a time of manufacture or after a time of manufacture, such as by an end user and/or a third party.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means within +/−10 percent of the stated value, or, if the value is zero, a reasonable range of values around zero. Modifications are possible in the described embodiments, and other embodiments are possible, within the scope of the claims.

What is claimed is:

1. A circuit comprising:
a detector coupled to a bus controller, the detector comprising:
a bus voltage detector configured to provide a bus voltage detected signal indicative of a bus voltage level of a bus voltage on a communication bus, wherein the bus controller is configured to operate in a first bus mode;
logic coupled to the bus voltage detector, the logic configured to:
determine whether the bus voltage is at a high bus voltage level or a low bus voltage level based on the bus voltage detected signal; and
instruct the bus controller to either continue operating in the first bus mode or to switch to operating in a second bus mode based on the determined bus voltage level.

2. The circuit of claim 1, wherein the logic is configured to instruct the bus controller to continue operating in the first bus mode responsive to receiving the bus voltage detected signal at a low voltage level.

3. The circuit of claim 1, wherein the logic is configured to instruct the bus controller to operate in the second bus mode in response to receiving the bus voltage detected signal at a high voltage level.

4. The circuit of claim 1, wherein the logic is configured to receive an indication of successful bus communication for a communication session between the bus controller and a host bus controller while the bus voltage is at the low bus voltage level, wherein the logic instructs the bus controller to continue operating in the first bus mode in response to receiving the indication of successful bus communication.

5. The circuit of claim 1, wherein the logic is further configured to output first and second bus mode threshold signals and a bus mode threshold select signal to a bus mode selector circuit, the detector further comprising the bus mode selector circuit that is configured to:
select one of the outputted first and second bus mode threshold signals as a mode selected threshold signal based on a voltage level of the bus mode threshold select signal; and
compare the bus voltage level of the bus voltage relative to the mode selected threshold signal to instruct a bus operating mode of the bus controller.

6. The circuit of claim 5,
wherein the first bus mode threshold signal is selected for comparison with the bus voltage in response to the bus mode selector circuit receiving the bus mode threshold select signal at a first voltage level, and
wherein the second bus mode threshold signal is selected for comparison with the bus voltage in response to the bus mode selector circuit receiving the bus mode threshold select signal at a second voltage level.

7. The circuit of claim 6, wherein the bus voltage corresponds to a bus signal on the communication bus, and the bus mode selector circuit is configured to:
compare the bus signal to the second bus mode threshold signal to detect the bus signal transitioning from a logic high state to a logic low state; and
provide a bus mode configuration signal at a high voltage level to the bus controller to set the bus operating mode of the bus controller to the second bus mode.

8. The circuit of claim 7, wherein the bus signal is a clock bus signal, and wherein the bus mode selector circuit comprises a voltage threshold selector and a clock edge detector, the voltage threshold selector is configured to:
receive the outputted first and second bus mode threshold signals and the bus mode threshold select signal; and
provide the second bus mode threshold signal to the clock edge detector in response to receiving the bus mode threshold select signal at the second voltage level.

9. The circuit of claim 8, wherein the clock edge detector is configured to:
detect a falling edge of the bus clock signal corresponding to the clock bus signal transitioning from the logic high state to the logic low state; and
provide the bus mode configuration signal at the high voltage level in response to detecting the falling edge of the bus clock signal.

10. The circuit of claim 1, further comprising the bus controller, the bus controller is configured to interpret bus signals on the communication bus using one or more first input logic level voltages when operating in the first bus mode and one or more second input logic level voltages when operating in the second bus mode.

11. The circuit of claim 10, wherein the bus controller is configured to communicate with a host bus controller using the communication bus, and the bus controller is configured to interpret the bus signals on the communication bus using the one or more first input logic level voltages during an initial communication session between the bus controller and the host bus controller.

12. The circuit of claim 11, wherein the detector is configured to receive an indication of successful bus communication from the bus controller for the initial communication session, and wherein the bus controller is configured to continue operating in the first bus mode in response to receiving the indication of successful bus communication.

13. A circuit comprising:
a detector having a first input and a second input, and an output, the first input coupled to a bus terminal and the second input coupled to a bus voltage threshold terminal;
a logic circuit having an input, and first and second outputs, the input coupled to the output of the detector; and
a bus mode selector circuit having first, second and third inputs, the first input coupled to the first output of the logic circuit, the second input coupled to the second output of the logic circuit, and the third input coupled to the bus terminal.

14. The circuit of claim 13, wherein the bus mode selector circuit comprises an output coupled to a bus controller and a fourth input coupled to a third output of the logic circuit.

15. The circuit of claim 14, wherein the detector is configured to provide at its output a bus voltage detected signal indicative of a bus voltage level of a bus voltage at the bus terminal, and the logic circuit is configured to:
determine whether the bus voltage is at a high bus voltage level or a low bus voltage level based on the bus voltage detected signal; and
instruct the bus controller to either continue operating in a first bus mode or to switch to operating in a second bus mode based on a determined bus voltage level.

16. The circuit of claim 15, wherein the logic circuit is further configured to output a first bus mode threshold signal at the first output of the logic circuit, a second bus mode threshold signal at the second output of the logic circuit, and a bus mode threshold select signal at the third output, the bus mode selector circuit configured to:
select one of the outputted first and second bus mode threshold signals as a mode selected threshold signal based on a voltage level of the bus mode threshold select signal; and
compare the bus voltage level of the bus voltage relative to the mode selected threshold signal to provide a bus mode configuration signal at its output.

17. The circuit of claim 16, wherein the bus mode selector circuit comprises a voltage threshold selector and a clock edge detector,
wherein the clock edge detector comprises first and second inputs and an output, the output of the clock edge detector being coupled to the bus controller, and the first input is coupled to the bus terminal, and
wherein the voltage threshold selector circuit comprises an output and first, second, and third inputs, wherein the first input is coupled to the first output of the logic circuit, the second output is coupled to the second output of the logic circuit and the third output is coupled to the third output of the logic circuit, and the output of the voltage threshold selector circuit is coupled to the second input of the clock edge detector.

18. The circuit of claim 17, wherein the voltage threshold selector is configured to:
receive the outputted first and second bus mode threshold signals at its respective first and second inputs and the bus mode threshold select signal at its third input; and
provide the second bus mode threshold signal at its output in response to receiving the bus mode threshold select signal.

19. A system comprising:
a power device comprising:
a bus controller coupled to a power management (PMBus) and configured to operate in a first bus mode, wherein in the first bus mode the bus controller uses a first input voltage threshold for interpreting bus signals transmitted on the PMBus;
a detector coupled to the PMBus and configured to:
determine a bus voltage level on the PMBus based on a respective bus signal of the bus signals; and
instruct the bus controller to either continue operating in the first bus mode or switch to operating in a second bus mode based on the determined bus voltage level, wherein in the second bus mode the bus controller uses a second input voltage threshold for interpreting the bus signals.

20. The system of claim 19, wherein the detector is configured to control the bus controller to continue operating in the first bus mode responsive to determining that the bus voltage level on the PMBus is at a low voltage level.
